(19) United States
(12) Patent Application Publication
(10) Pub. No.: US 2006/0081896 A1
(43) Pub. Date: Apr. 20, 2006

(54) Semiconductor device and method for forming the same

(75) Inventor: Shigenobu Maeda, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/254,171

(22) Filed: Oct. 18, 2005

(30) Foreign Application Priority Data
Oct. 20, 2004 (KR) 10-2004-0084055

(51) Int. Cl. H01L 29/76

(52) U.S. Cl. 257/288

(57) ABSTRACT

The present invention disclosed herein is a semiconductor device and a method for forming the same. The semiconductor device includes a first semiconductor pattern defining an active region, second semiconductor patterns placed on the first semiconductor pattern apart from each other, an insulated gate electrode spaced apart from the second semiconductor patterns to be placed therebetween, and stress generating patterns filling intervals between the insulated gate electrode and the second semiconductor patterns. The stress generating patterns apply a stress to a channel region defined by the first semiconductor pattern under the gate electrode, thereby increasing carrier mobility.

### CLAIM OFF PRIORITY

The present application claims priority from Korean Patent Application No. 10-2004-0084055 filed on Oct. 20, 2004, the contents of which are hereby incorporated by reference herein in their entirety.

### FIELD OF THE INVENTION

The present invention is directed generally to semiconductor devices and a method for forming the same, and more particularly to a MOS Field Effect Transistor and a method for forming the same.

### BACKGROUND OF THE INVENTION

The MOSFET is an important device in semiconductor integrated circuits. The MOSFET includes source/drain regions formed on a substrate, and a gate electrode on a channel defined therebetween. The gate electrode is insulated from the channel by a gate insulating layer. An electric field is created by applying proper bias voltage to the gate electrode while the MOSFET is operated. The electric field is used to control formation of a channel under the gate electrode. In addition, proper bias voltage is applied to the source/drain regions to create the electric field crossing over a channel region, thereby controlling mobility of carriers. For example, if the channel is formed (turned on), electrons flow from a source region to a drain region. If the channel is not formed, electrons do not flow between the source region and the drain region. Depending on an on and off state of the channel, the connection or cut-off of integrated circuits is controlled.

The speed or velocity (v) of carriers (electrons or holes) crossing channel regions is given by the following mathematical equation 1.
v=μE (Mathematical Equation 1)

In Equation 1, “E” represents electric field crossing the channel region, and “μ” represents carrier mobility.

Since electric field E has a constant value generally, it is necessary to increase the mobility (μ) so as to improve the speed of devices.

To address this, methods for changing a bandgap have been introduced.

The first method is a method for forming a silicon layer on a relaxed silicon-germanium layer. This method includes the steps of growing a silicon-germanium layer on a silicon substrate using an epitaxial method and growing a silicon layer on a silicon-germanium epitaxial layer using an epitaxial method. The silicon-epitaxial layer is strained by the silicon-germanium epitaxial layer having a large lattice constant. For this reason, a bandgap is changed, thereby increasing the carrier mobility. In this method, relaxing the silicon-germanium epitaxial layer is desrirable, and there are ongoing efforts to accomplish this.

However, this method requires various processes such as forming a strained silicon-germanium layer, relaxing the strained silicon-germanium layer, and forming a silicon layer, so that device yield is reduced.

The second method is to change a bandgap of a channel region by applying a physical stress to the channel region. This method is disclosed by T. Ghani, et al., in technical digest IEDM, 2003, pp. 978, entitled “A 90 nm High Volume Manufacturing Logic Technology Featuring Novel 45 nm Gate Length Strained Silicon CMOS Transistor”. FIG. 1 herein schematically shows a MOSFET formed employing this method. FIG. 2 is a plan view of a semiconductor device. In FIGS. 1 and 2, reference numerals 11, 12, 13, 15, 17, 19, 21, and 23 indicate a silicon substrate, an active region, a device isolation layer, a gate insulating layer, a gate electrode, a silicon-germanium layer, a gate spacer, and a channel region, respectively. Referring to FIG. 1, a device isolation layer 13, a gate electrode 17, and a gate spacer 21 are formed. Source/drain regions at both sides of a gate spacer 21 are etched. A silicon-germanium layer 19 is grown in the etched region by an epitaxial method. The silicon-germanium layer 19 is contacted by the gate spacer 21 and the device isolation layer 13. Since the silicon-germanium single crystal has a larger lattice constant than a silicon single crystal, a compressive stress is applied to a channel region in the direction of arrows, thereby changing a bandgap thereof.

The magnitude of the compressive stress applied to the channel region depends on a distance (d1) from the device isolation layer 13 to the gate spacer 21, that is, a width (D1) of the silicon-germanium layer. These distances (d1 and D1) can be selected according to a design rule. It is difficult to engineer the magnitude of the compressive stress applied to the channel region.

Referring to FIG. 2, three MOSFETs are formed in one active region 12. The magnitude of a stress applied to a channel region of each of the MOSFETs is different according to the widths 19a˜19d of the silicon-germanium layer. Depending on a design rule, the distances (d4 and d7) from the gate spacer 21 to the device isolation layer 13 may be different from the distances (D5 and D6) between neighboring gate spacers 21. Accordingly, the compressive stress is differently applied to the channel region of each of the MOSFETs, so that each of the MOSFETs is operated at a different speed.

With high integration of semiconductor devices in condsideration of high-performance, high-speed, economics, there are several problems such as a short channel effect like punch-through characteristic as a channel length of a conventional planar MOSFET becomes short, the increment of a parasitic capacitance (a junction capacitance) between a junction region and a substrate, the increment of leakage current. In order to overcome theses problems, an SOI technique for fabricating a thin body MOSFET using a Silicon-On-Insulator (SOI) substrate has been introduced. This technique will be described referring to FIG. 3 because it is unsuitable to apply the method of FIG. 1 to the MOSFET using the SOI substrate.

In FIG. 3, reference numerals 11, 53, 12, 15, 17, 19, 21, and 23 indicate a supporting substrate, a buried oxide layer, an active region (an SOI layer), a gate insulating layer, a gate electrode, a silicon-germanium layer, a gate spacer, and a channel region, respectively. Referring to FIG. 3, in the case of the SOI technique, after forming a transistor (a silicon-germanium layer 19), an insulating layer corresponding to the device isolation layer 13 of FIG. 1 is formed. Accordingly, the stress by the silicon-germanium layer 19 is discharged in the direction of arrows (in the opposite direction of a channel region), and the stress is not applied to the channel region 23.

### SUMMARY OF THE INVENTION

It is therefore a feature of the present invention to provide a semiconductor device capable of improving an operation speed without regard to a design rule and a method for forming the same.

According to an aspect of the present invention, there is provided a semiconductor device, comprising: a first semiconductor pattern defining an active region; a gate electrode on the first semiconductor pattern with a gate insulating layer interposed between the gate electrode and the first semiconductor pattern; a gate spacer formed at both sidewalls of the gate electrode; and stress generating patterns formed on the first semiconductor pattern under the gate spacer.

According to another aspect, the invention is directed to a method of forming a semiconductor device comprising: forming a first semiconductor pattern defining an active region; interposing a gate insulating layer on the first semiconductor pattern to form a gate electrode; interposing a buffer layer on both sidewalls of the gate electrode to form a sacrificial spacer; forming an epitaxial second semiconductor pattern on the first semiconductor pattern outside the sacrificial spacer; removing the sacrificial spacer; and forming stress generating patterns on the first semiconductor pattern exposed by removing the spacer.

According to another aspect of the present invention, there is provided a method for forming a semiconductor device. The method comprises: forming a first semiconductor pattern defining an active region; forming an insulated gate electrode on the first semiconductor pattern; forming second semiconductor patterns having intervals on the first semiconductor pattern at both sides of the insulated gate electrode; and forming stress generating patterns filling the intervals.

In accordance with this method, unlike a conventional art, the stress generating patterns are not directly in contact with a device isolation layer and defined between the second semiconductor pattern and the gate electrode.

In some embodiments, the first semiconductor pattern is formed of a silicon substrate, and the stress generating patterns are formed of a silicon-germanium epitaxial layer. Therefore, the stress generating patterns provide a compressive stress to a first semiconductor pattern (a channel region) under the gate electrode therebetween.

In some embodiments, the first semiconductor pattern is formed of a silicon-germanium substrate, and the stress generating patterns are formed of a silicon epitaxial layer. Accordingly, the stress generating patterns provide a strain with respect to the first semiconductor pattern (a channel region) under the gate electrode therebetween.

In some embodiments, forming intervals on the first semiconductor pattern at both sides of the insulated gate electrode includes: forming sacrificial spacers on both lateral sides of the insulated gate electrode; forming second semiconductor patterns on the first semiconductor pattern outside the sacrificial spacer; and removing the sacrificial spacers; and removing the sacrificial spacers. Accordingly, the stress generating patterns are formed in a self-aligned manner. That is, the stress generating patterns are formed at positions where the sacrificial spacers are removed. The width of the stress generating patterns having an influence on the compressive stress applied to the channel region is determined not by a design rule but by the width of the sacrificial spacers.

In some embodiments, a part of the first semiconductor pattern exposed by the intervals is etched so as to lower a top surface thereof. Accordingly, the height of the first semiconductor pattern under the gate electrode is higher than a bottom surface of the stress generating patterns. For this reason, a compressive stress may be efficiently applied to the channel region under the gate electrode.

In some embodiments, the second semiconductor patterns are partially or wholly removed when the first semiconductor pattern exposed by the intervals is etched. In this case, in order to prevent etching of the gate electrode, the gate electrode may be formed after depositing a conductive layer and a capping layer covering it sequentially, and then patterning them.

In some embodiments, second semiconductor patterns are formed on the first semiconductor pattern outside the sacrificial spacers by selectively forming an epitaxial semiconductor layer of the same type as the first semiconductor pattern on the first semiconductor pattern exposed outside the sacrificial spacers using an epitaxial growing method.

In some embodiments, the stress generating patterns are formed by forming a hetero epitaxial semiconductor layer having a larger lattice constant than the first and second semiconductor patters using an epitaxial growing method. For instance, in the case that the first and second semiconductor patterns are silicon single crystalline, the hetero epitaxial layer is formed of single crystalline silicon-germanium. Since single crystalline silicon-germanium has a larger lattice constant than single crystalline silicon, a compressive stress is applied to a channel region under the gate electrode.

In some embodiments, the stress generating patterns are formed by forming a silicon nitride layer on an entire surface so as to fill the intervals.

In some embodiments, after forming the sacrificial insulating spacer, impurity ions are implanted to form source/drain regions. Moreover, after removing the sacrificial insulating spacer, impurity ions are implanted to form source/drain extension regions.

In some embodiments, forming the first semiconductor pattern comprises the steps of: preparing an SOI substrate in which a supporting semiconductor substrate, a buried oxide layer, and a first semiconductor substrate are sequentially stacked; and patterning the first semiconductor substrate using an etch mask defining an active region until the buried oxide layer is exposed.

In some embodiments, forming the first semiconductor pattern comprises the steps of: preparing a first semiconductor substrate; and etching the first semiconductor substrate by a predetermined depth using an etch mask defining an active region; and filling insulating materials to form a device isolation layer.

According to another aspect of the present invention, there is provided a semiconductor device. The semiconductor device includes a semiconductor pattern, a gate electrode, and stress generating patterns. The semiconductor pattern includes source/drain regions, a channel region, and source/drain extension regions, which are placed between the source/drain regions and the channel region. Surfaces of the source/drain extension regions are lower than the channel region and the source/drain regions. The gate electrode is formed on the channel region with a gate insulating layer interposed between the gate electrode and the channel region. The stress generating patterns fill the intervals on the source/drain extension regions defined between the channel region and the source/drain regions.

In the semiconductor device, the stress generating patterns are defined in the intervals between the source/drain regions and the gate electrode, that is, on the source/drain extension regions in a self-aligned manner. The intervals between the source/drain regions and the gate electrode may be maintained constantly irrespective of a design rule.

In some embodiments, an upper surface of the channel region is higher than that of the source/drain extension regions. Accordingly, a compressive stress is efficiently applied to the channel region.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a schematic cross-sectional view of a MOS Field Effect Transistor formed on a bulk silicon substrate according to conventional art.

FIG. 2 is a plan view of a semiconductor device formed on a bulk silicon substrate according to conventional art.

FIG. 3 is a cross-sectional view illustrating problems that arise in applying conventional art to an SOI substrate.

FIGS. 4A to 4H are schematic cross-sectional views illustrating a method for forming a semiconductor device according to one embodiment of the present invention.

FIG. 5 is a schematic cross-sectional view of a semiconductor substrate showing a semiconductor device formed according to one embodiment of the present invention.

FIG. 6 shows a result of a simulation for confirming magnitude of a stress applied to a channel region in a semiconductor device of FIG. 5.

FIGS. 7A to 7F are schematic cross-sectional views of a semiconductor substrate illustrating a method for forming a semiconductor device according to another embodiment of the present invention.

FIGS. 8A and 8B are schematic cross-sectional views of a semiconductor substrate illustrating a method for forming a semiconductor device according to another embodiment of the present invention.

FIG. 9 is a schematic cross-sectional view showing a semiconductor device formed according to another embodiment of the present invention.

FIGS. 10A and 10B schematically show a method for forming a semiconductor device according to another embodiment of the present invention.

FIGS. 11A and 11B are schematic cross-sectional views showing a semiconductor device according to some embodiments of the present invention.

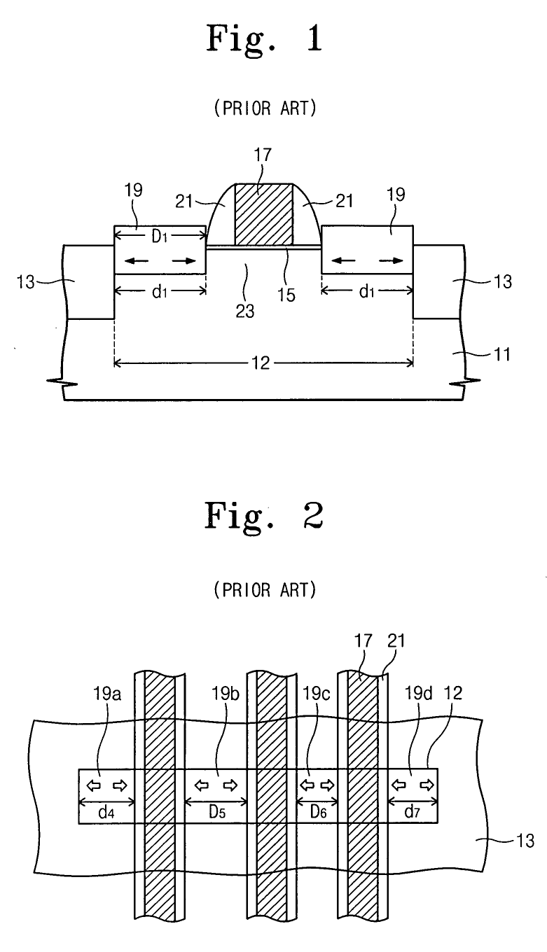

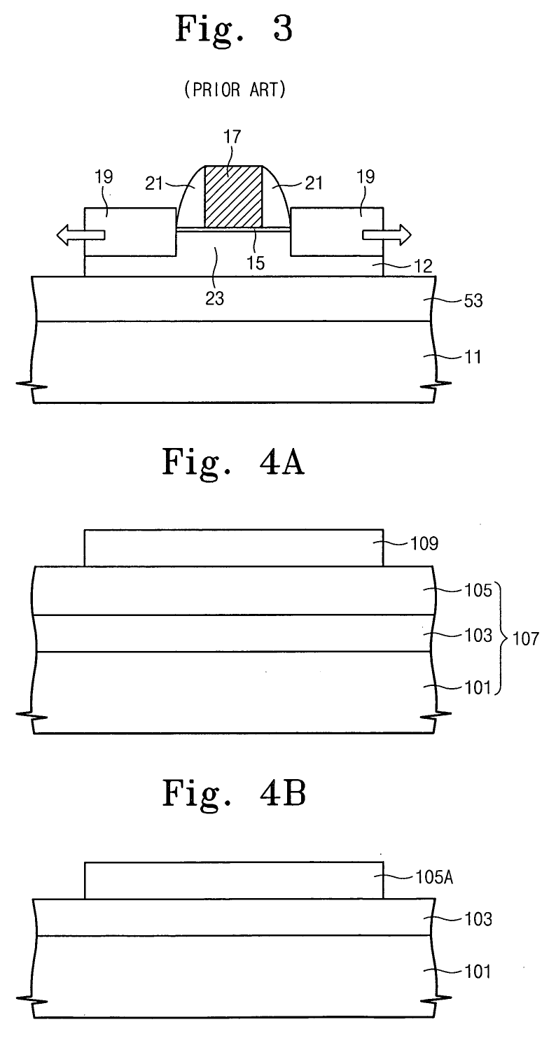

### DETAILED DESCRIPTION OF EMBODIMENTS OF THE INVENTION

In the specification, the thickness of layers and regions are exaggerated for clarity. It will be understood that when an element such as a layer, region or substrate is referred to as being “on” or “onto” another element, it can be directly on the other element or intervening elements may also be present. It will also be understood that, although the terms first, second, etc. may be used herein to describe various elements, these elements should not be limited by theses terms. These terms are only used to distinguish one element from another. For example, a first element could be termed a second element, and similarly, a second element could be termed a first element, without departing from the scope of the present invention.

The present invention relates to a method for forming a semiconductor device, and more specifically, to a MOSFET and a method for forming a MOSFET. Hereinafter, a P-type MOSFET and a method for forming the same will be described by way of example. It will be understood that the invention is also applicable to an N-type MOSFET.

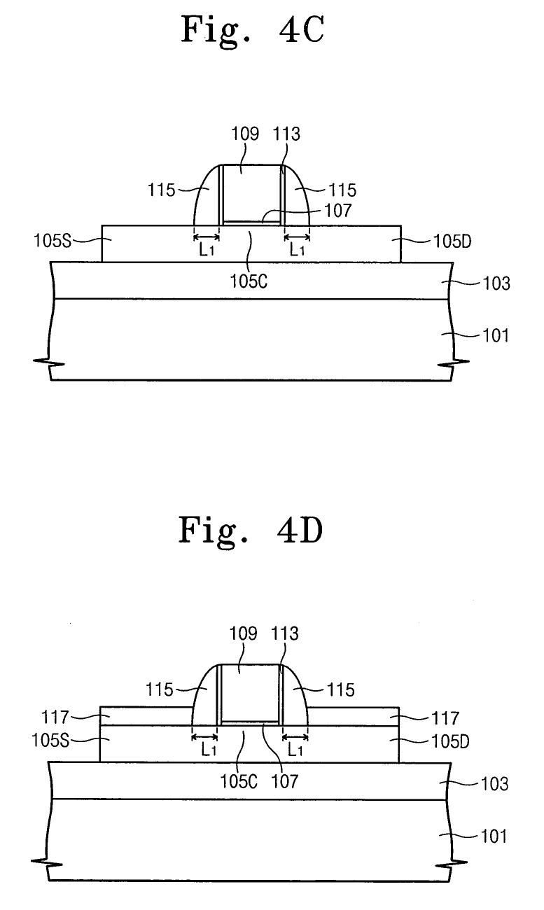

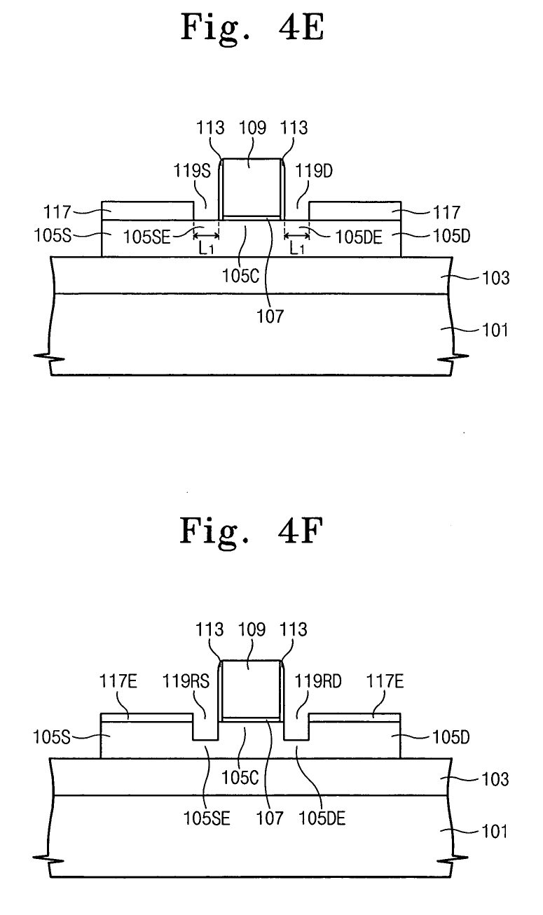

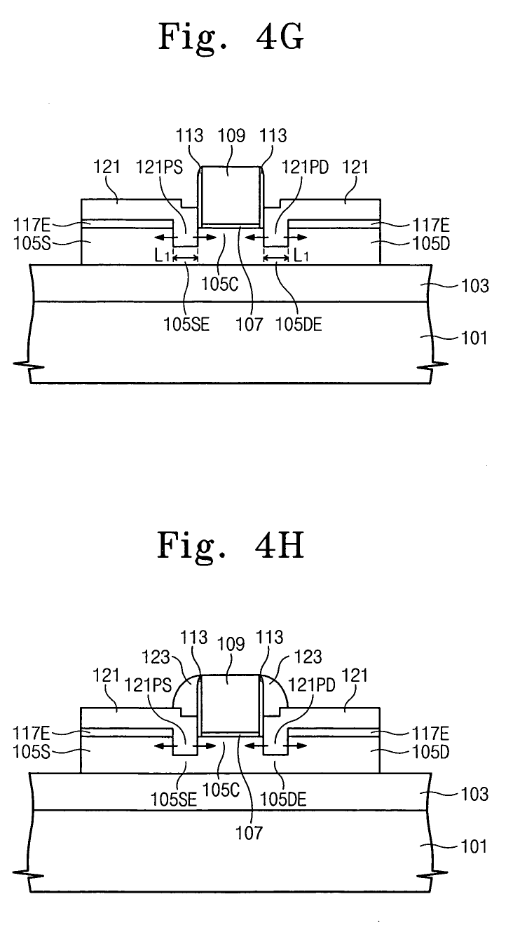

FIGS. 4A to 4H are cross-sectional views illustrating a method for forming a semiconductor device according to a preferred embodiment of the present invention. The present embodiment relates to a method for forming a semiconductor device using an SOI substrate.

Referring to FIG. 4A, an SOI substrate 107 is prepared. The SOI substrate 107 is prepared in a well known manner. The SOI substrate 107 is comprised of a sequentially stacked structure of a supporting semiconductor substrate 101, a buried oxide layer 103, and a semiconductor substrate 105 to be an active region. An etch mask 109 defining the active region is formed on the semiconductor substrate 105. A region of the semiconductor substrate 105 covered with the etch mask 109 is to be the active region.

Referring to FIG. 4B, the semiconductor substrate exposed by the etch mask 109 is removed to form a silicon pattern 105A defining the active region. An etch process is performed until the buried oxide layer 103 is exposed. The etch mask 109 is removed. After forming the silicon pattern 105A, impurity ions for channel doping are implanted. For channel doping, in the case of a P-MOSFET, n-type impurities are implanted, and in case of an N-MOSFET, p-type impurities are implanted.

Referring to FIG. 4C, a gate insulating layer 107 is interposed on the silicon pattern 105A to form a gate electrode 109. The gate insulating layer and a gate electrode layer are formed on the silicon pattern 105A and then patterned to form the gate electrode 109 that is insulated from the silicon pattern 105A by the gate insulating layer 107. A capping layer (not shown) may be further formed on the gate electrode layer. The capping layer is formed of a material having an etch selectivity with respect to a sacrificial spacer 115 to be formed in a subsequent process. For example, the capping layer is formed of a silicon oxide layer. The gate electrode 109 is formed of a conductive material and may be formed of doped polysilicon, metal materials, silicide, or a combination thereof.

Referring now to FIG. 4C, a buffer layer 113 is formed on both sidewalls of the gate electrode 109. The buffer layer 113 is formed of a material having an etch selectivity with respect to a sacrificial spacer 115 to be formed in a subsequent process. For example, the buffer layer 113 may be formed of a silicon oxide layer, and the sacrificial spacer 115 may be formed of a silicon nitride layer. That is, the buffer layer 113 may be formed by performing an etch-back process after forming a silicon oxide layer using a vapor deposition method. Accordingly, a silicon oxide layer remains at the buffer layer 113 on both sidewalls of the gate electrode 109.

After forming a spacer material layer having an etch selectivity with respect to the buffer layer 113, the sacrificial spacer 115 is formed on both sidewalls of the gate electrode 109 by etching-back the spacer material layer. The sacrificial spacer 115 is formed of a silicon nitride layer. The sacrificial spacer 115 has a predetermined width L1. The width L1 of the sacrificial spacer 115 depends on the height of the gate electrode 109 and the deposition thickness of the spacer material layer, which are readily controlled.

A semiconductor pattern under the gate electrode 109 functions as a channel region 105C. The semiconductor pattern at both sides of the sacrificial spacer is a region where a source region 105S and a drain region 105D are formed. An ion implantation process for the source/drain regions 105S and 105D is performed after forming the sacrificial spacer 115.

Referring to FIG. 4D, a semiconductor pattern outside the sacrificial spacer 115, that is, an epitaxial silicon layer 117 on the source/drain regions 105S and 105D is formed using an epitaxial growth technique. When the epitaxial silicon layer 117 is formed, impurity ions may be doped in in-situ manner. According to this, the epitaxial silicon layer 117 functions as the source/drain regions.

Referring to FIG. 4E, the sacrificial spacer 115 is removed. The sacrificial spacer 115 may be removed using a phosphoric acid. By removing the sacrificial spacer 115, intervals 119S and 119D corresponding to the width L1 of the sacrificial spacer 115 are defined between the epitaxial silicon layer 117 and the gate electrode 109. That is, a staircase structure is formed by the epitaxial silicon layer 117 and the silicon pattern 105A. Also, a semiconductor pattern under these intervals 119S and 119D is a region where a source extension region 105SE and a drain extension region 105DE are formed. An ion implantation process for the source/drain extension regions 105SE and 105DE is performed after removing the sacrificial spacer 115.

Referring to FIG. 4F, the source/drain extension regions 105SE and 105DE exposed under the intervals 119S and 119D are partially removed to form recessed regions 119RS and 119RD. Thus, upper surfaces of the source/drain extension regions 105SE and 105DE are lower than those of the source/drain regions 105S and 105D and the channel region 105C. The silicon pattern 105A has the recessed regions 119SR and 119RD. The recessed regions 119RS and 119RD are formed under the removed sacrificial spacer 115 in a self-alignment technique, so that the width of the recessed regions 119RS and 119RD has the width L1 corresponding to the width of the removed sacrificial spacer 115.

In this case, when the semiconductor pattern under the intervals 119S and 119D is partially removed, the epitaxial silicon layer 117 may be partially or wholly removed. In the event that a part of the epitaxial silicon layer 117 is removed, an epitaxial silicon layer 117E remains on the source/drain regions 105S and 105D.

Referring to FIG. 4G, a silicon-germanium epitaxial layer 121 is formed using an epitaxial growth technique so as to fill the recessed regions 119RS and 119RD. The silicon-germanium epitaxial layer 121 is selectively grown on the silicon pattern of the recessed regions 119RS and 119RD, and the residual epitaxial silicon layer 117E. A compressive stress is applied to a channel region 105C by silicon-germanium epitaxial layers 121PS and 121PD (hereinafter, referred to as a “stress generating patterns”). The silicon-germanium epitaxial layer has a larger lattice constant than the silicon pattern. The stress generating patterns 121PS and 121PD has a strain in the direction of the arrows shown in FIG. 4G, and therefore, the channel region receives a compressive stress.

The stress generating patterns 121PS and 121PD are formed under the removed sacrificial spacer 115 in a self-alignment technique, and their width is determined by the width of the removed sacrificial spacer 115. In accordance with the present invention, the width of the stress generating patterns may be constant independent of the design rule and size of the semiconductor pattern 105A. The stress generating patterns 121PS and 121PD are located between the source/drain regions 105S and 105D, and the channel region 105C.

Referring to FIG. 4H, a gate spacer 123 is formed on both sidewalls of the gate electrode 109. The gate spacer 123 is formed by forming a gate spacer insulating layer and then etching-back. The gate spacer 123 fills a space of the removed sacrificial spacer 115.

A silicide layer (not shown) is formed on an upper portion of the source/drain regions 105S and 105D and the gate electrode 109 by performing a silicidation process. In this case, the silicide layer is formed at the silicon-germanium layer outside the gate spacer 123. It is possible to prevent a loss or an attack of the source/drain regions 105S and 105D during the silicidation process. Moreover, a silicide layer may be formed on the gate electrode 109. As is well known, a silicidation process may be performed by depositing a metal such as titanium, cobalt, nickel and then performing a thermal process. During the silicidation process, a novel metal and silicon germanium layer react to form a silicide layer.

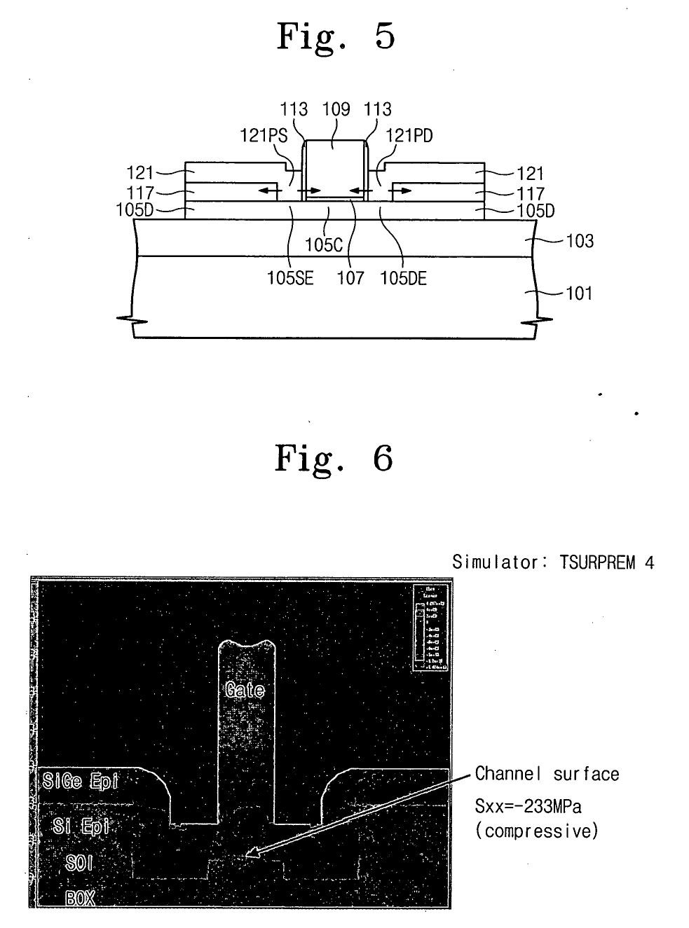

FIG. 5 schematically shows a semiconductor device formed according to another embodiment and shows a subsequent process of FIG. 4E. The process for etching a part of the silicon pattern 105A under the sacrificial spacer 115 in the above-described embodiments is performed and however, their process is omitted in the present embodiment. Accordingly, the epitaxial silicon layer 117 is not etched, and the stress generating patterns 121PS and 121PD fill the intervals 119S and 119D defined by the epitaxial silicon layer 117 and the gate electrode 109. In the present invention, since the silicon pattern 105A is not etched, the thin film SOI technique is usefully applicable to a thin body transistor.

FIG. 6 shows a simulation result for confirming a size of a stress applied to the channel region 105C in the semiconductor device of FIG. 5. The simulation is conducted using a tool for calculating a stress created in the semiconductor device. In this simulation, the thickness of the silicon pattern 105A, the epitaxial silicon layer 117, a silicon-germanium layer being a stress generating pattern, a buffer layer 113, and a buried oxide layer are set to 10 nm, 30 nm, 20 nm, 5 nm, and 200 nm, respectively, and the length of the gate electrode 109 is set to 20 nm, and the distance between the gate electrode 109 and the epitaxial silicon layer 117, that is, the width of the intervals 119S and 119D is set to 50 μm. Also, stress of about 1 GPa is applied to the silicon-germanium layer 121. As shown in FIG. 6, compressive stress of about 233 MPa is applied to the channel region 105C. At a stress of about 200 MPa, the on current is increased at a approximately 5% in the MOSFET.

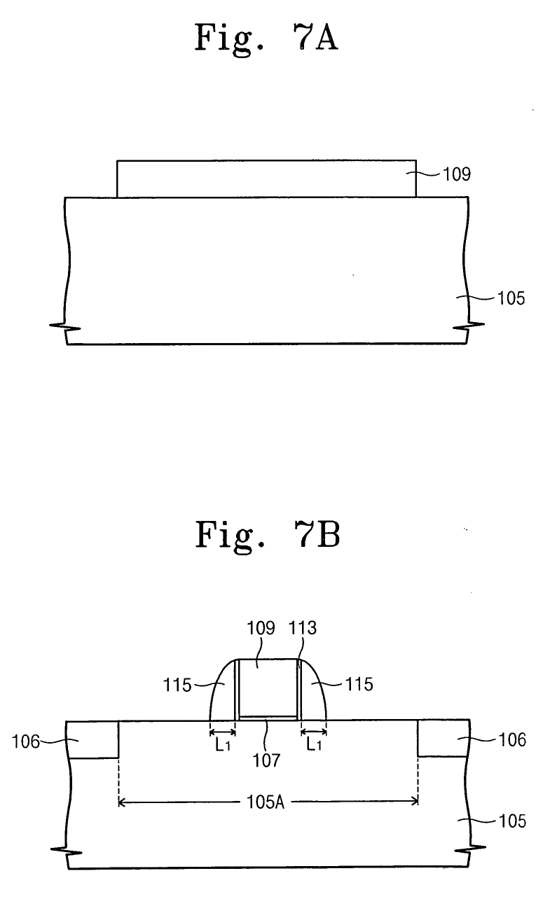

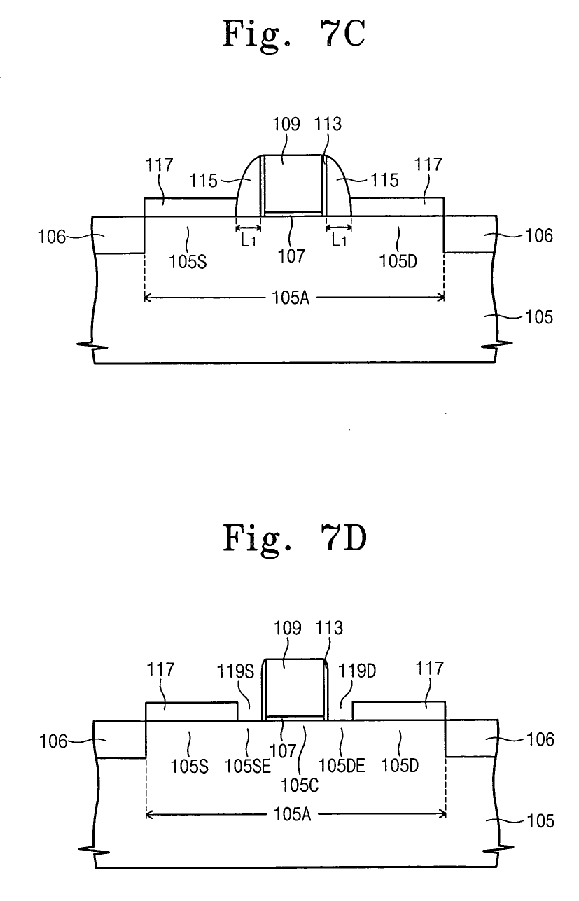

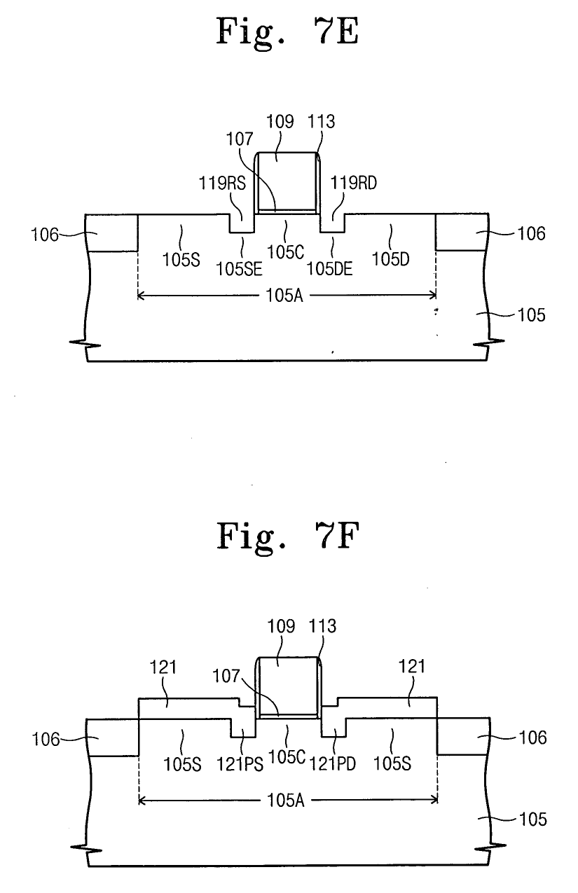

While these embodiments are described employing the SOI substrate, a bulk silicon substrate is applicable within the scope of the invention. This will be described referring to FIGS. 7A to 7F.

Referring to FIG. 7A, a bulk silicon substrate 105 is prepared. An etch mask 109 defining an active region is formed on the silicon substrate 105.

Referring to FIG. 7B, the exposed silicon substrate 105 is etched using the etch mask 109 to form a trench defining a device isolation region. Then, an insulating material is filled in the trench to form a device isolation layer 106, thereby forming the silicon pattern 105A. The silicon pattern 105A is an active region that is insulated by the device isolation layer 106. The etch mask 109 is removed, and then an ion implantation process for forming a channel is performed. In the same way as mentioned above, a gate insulating layer 107, a gate electrode 109, a buffer layer 113, and a sacrificial spacer 115 are formed, and then source/drain regions 105S and 105D are formed.

Referring to FIG. 7C, an epitaxial silicon layer 117 is formed on the silicon pattern 105A at both sides of the sacrificial spacer 115, that is, the source/drain regions 105S and 105D, using a selective epitaxial growth technique.

Referring to FIG. 7D, the sacrificial spacer 115 is removed using a phosphorous acid, and then an impurity ion implantation process is performed to form the source/drain extension regions 105SE and 105DE. By removing the sacrificial spacer 115, the intervals 119S and 119D are formed between the gate electrode 109 and the epitaxial silicon layer 117. A silicon pattern under the intervals 105SE and 105DE are the source/drain extension regions 119S and 119D.

Referring to FIG. 7E, an etch-back process is performed using a gas for selectively etching silicon. A part of the silicon pattern under the intervals 119S and 119D is removed to form recessed region 119RS and 119RD. At this time, the epitaxial silicon layer 117 is removed. Also, all epitaxial silicon layers 117 may be removed according to an etch degree. As a result, upper surfaces of the source/drain extension regions 105SE and 105DE become lower than those of the source/drain regions 105S and 105D and the channel region 105C.

Referring to FIG. 7F, a silicon-germanium epitaxial layer 121 is formed using an epitaxial growth technique so as to fill the recessed regions 119RS and 119RD. Silicon-germanium epitaxial layers 121PS and 121PD (stress generating patterns) filling the recessed regions 119RS and 119RD apply a compressive stress to the channel region.

In accordance with the present embodiment, the stress generating patterns 121PS and 121PD are not in contact with the device isolation layer 106. In addition, the stress generating pattern 121PS and 121PD are formed in a self-alignment manner and thereby maintain the width thereof.

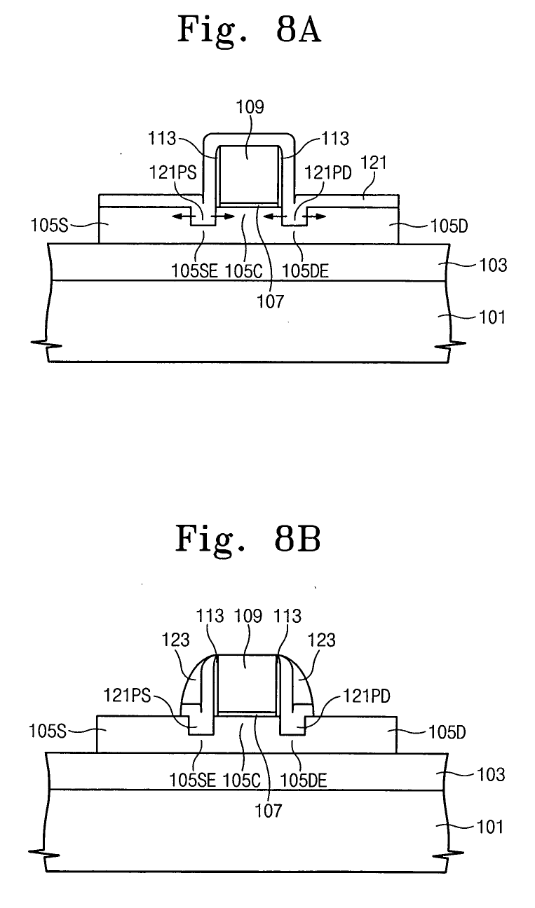

The stress generating patterns are formed of a silicon-germanium epitaxial layer throughout the embodiments, and however, they should not be limited by this. The stress generating patterns may be formed of another material. For example, if a semiconductor pattern is formed of silicon-germanium, stress generating patterns may be formed of a silicon epitaxial layer. In this case, a strain stress is applied to the channel region 105C, so that the mobility of electrons becomes increased in an N-type MOSFET. If the stress generating patterns are filled in the intervals or recessed regions, any material capable of applying a stress to the channel can be used. One example is silicon nitride. Silicon nitride includes at least silicon atoms and nitrogen atoms, and examples include silicon nitride SiN, silicon oxynitride and so forth. This will be described referring to FIGS. 8A and 8B.

After performing the processes described referring FIGS. 4A to 4E, the silicon pattern 105A is partially etched to form recessed regions 119RS and 119RD. Unlike the above-described embodiments, as shown in FIG. 8A, the silicon nitride layer 121 is formed not by an epitaxial growth technique but by a chemical vapor deposition method. Silicon nitride layers 121PS and 121PD in the recessed regions 119RS and 119RD apply a compressive stress to the channel region 105C.

Referring to FIG. 8B, a gate spacer 123 is formed on sidewalls of the gate electrode 109 by performing an etch-back process with respect to silicon nitride after forming silicon nitride with a spacer insulating layer. In this case, the etch-back process with respect to silicon nitride is performed until the silicon pattern 105A is exposed.

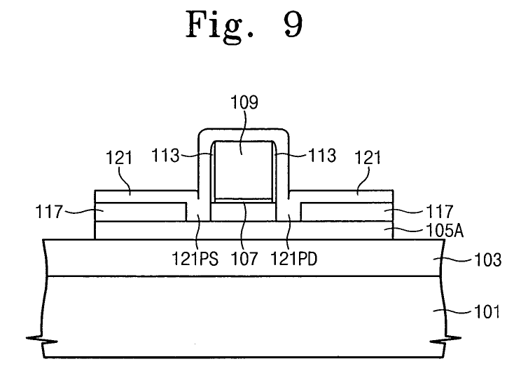

In the present embodiment, like FIG. 5, an etch process with respect to the silicon pattern 105A may not performed. As shown in FIG. 9, the silicon nitride layers 121, 121PS, and 121PD applying a compressive stress to the channel region 105C are formed to fill the intervals 119S and 119D between the epitaxial silicon layer 117 and the gate electrode 109.

In addition, a method for forming stress generating patterns with silicon nitride is applicable to a bulk silicon substrate.

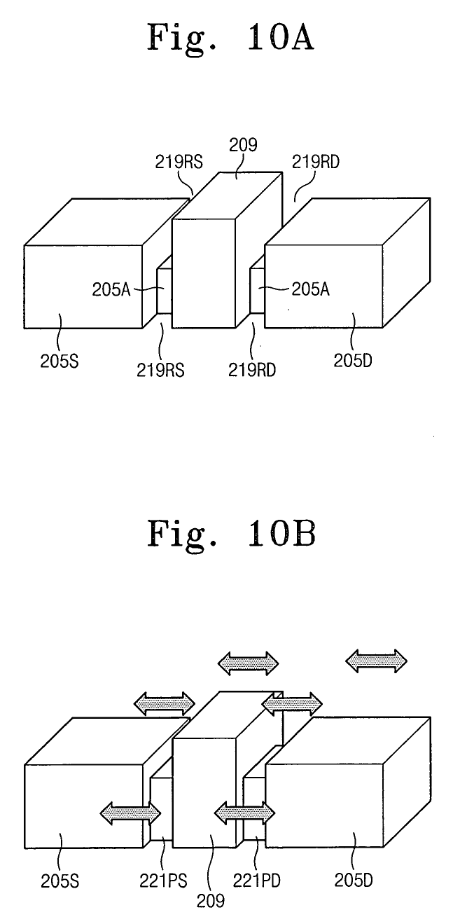

The method of the invention for forming the MOSFET is applicable to double-gate or triple-gate transistor process using a silicon pin. This will be described referring to FIGS. 10A and 10B. To simplify the figures, a supporting semiconductor substrate and a buried oxide layer are not shown.

Referring to FIG. 10A, a silicon substrate on the buried oxide layer is etched to form a silicon pattern defining an active region, that is, a silicon pin 205A. A gate electrode 209 and a sacrificial spacer are formed. An epitaxial silicon layer is formed. The sacrificial spacer is removed to form recessed regions 219RS and 219RD.

Referring to FIG. 10B, stress generating patterns 221PS and 221PD filling the recessed regions 219RS and 219RD. The stress generating patterns 221PS and 221PD may be formed of an epitaxial silicon-germanium layer or a silicon nitride layer.

A gate electrode 209 is formed on an upper surface and on both sides of the silicon pin 205A. In the same way, source/drain regions 205S and 205D are formed on the upper surface and both sides of the silicon pin 205A. Accordingly, recessed regions 219RS and 219RD are defined at three sides between the gate electrode 209 and the source/drain regions 205S and 205D, and the stress generating patterns 221PS and 221PD are formed therein. A stress is applied to the upper surface and both sides of the semiconductor pin 205A that functions a channel region. A gate insulating layer (not shown) is interposed between the gate electrode 209 and the semiconductor pin 205A. In this case, if a thick insulating layer is located between the gate electrode 209 and the upper surface of the semiconductor pin 205A, only both sides of the semiconductor pin 205A may function as a channel region.

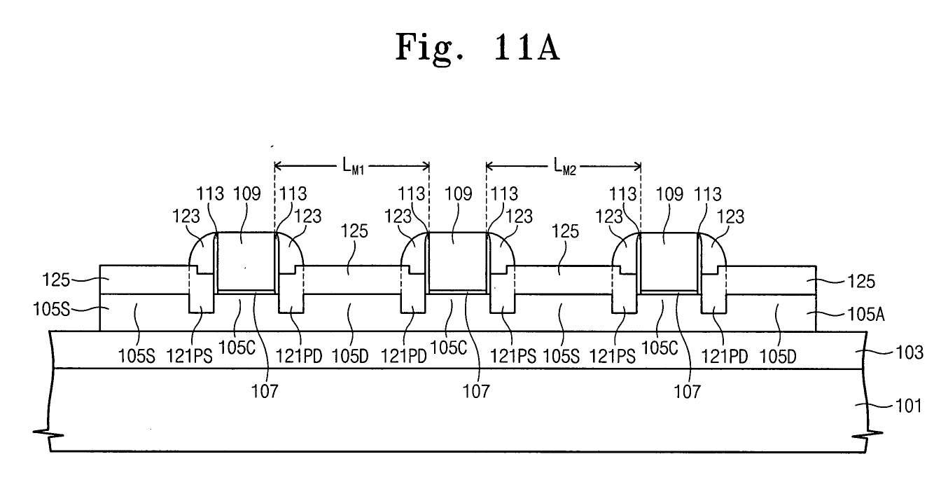

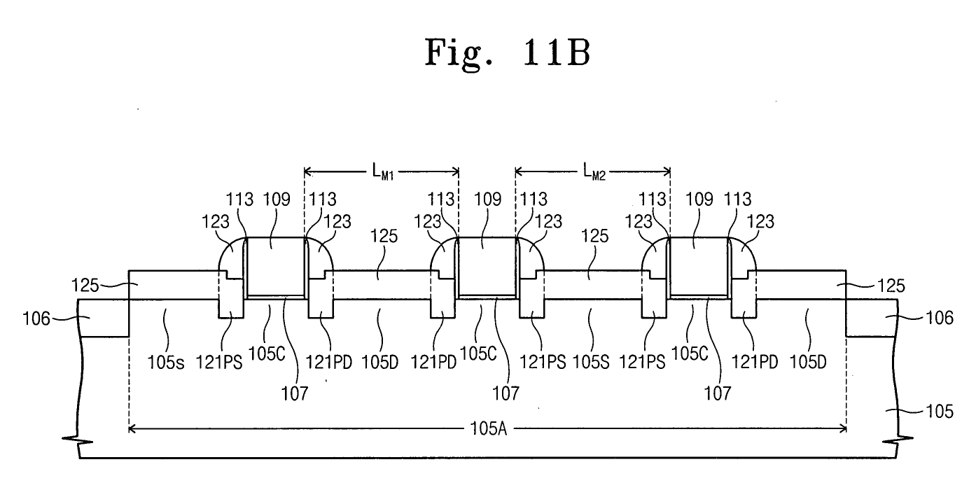

FIGS. 11A and 11B show several MOSFETs that are formed on a SOI substrate and a bulk substrate, respectively, according to the present invention. Referring to FIGS. 11A and 11B, all stress generating patterns 121PS and 121PD are located under the gate spacer 123 in a self-alignment manner. Also, the stress generating patterns 121PS and 121PD are located between the source/drain regions 105S and 105D and the channel region 105C. Accordingly, it is possible to form the stress generating patterns 121PS and 121PD to a given width independent of a design rule. As a result, a stress having the same magnitude may be applied to channel regions of the MOS transistors. For example, even if mis-alignment occurs during a photolithography process for forming a gate electrode, or the distances LM1 and LM2 between neighboring gate electrodes 109 are different from each other, the width of the stress generating patterns 121PS and 121PD is self-aligned under the gate spacer 123 to be maintained constant. The magnitude of the stress generating patterns 121PS and 121PD may be maintained constant irrespective of the size of the semiconductor pattern 105A defining the active region.

The silicide layer 125 is formed on the source/drain regions 105S and 105D. The silicide layer may be formed on the gate electrode 109. Referring to FIG. 11B, the stress generating patterns 121PS and 121PD are not in contact with the device isolation region 106 in MOS transistors formed on a bulk silicon substrate.

As previously described, since stress generating patterns applying a stress to a channel region are formed in a self-alignment manner, it is possible to form the stress generating patterns irrespective of a design rule.

While the present invention has been particularly shown and described with reference to embodiments thereof, it will be understood by those skilled in the art various changes in form and details may be made therein without departing from the spirit and scope of the invention as defined the appended claims and their equivalents.

1. A semiconductor device, comprising:
a first semiconductor pattern defining an active region;
a gate electrode on the first semiconductor pattern with a gate insulating layer interposed between the gate electrode and the first semiconductor pattern;
a gate spacer formed at both sidewalls of the gate electrode; and
stress generating patterns formed on the first semiconductor pattern under the gate spacer.

2. The semiconductor device of claim 1, further comprising second semiconductor patterns formed on the first semiconductor pattern outside of the gate spacer.

3. The semiconductor device of claim 1, wherein an upper surface of the first semiconductor pattern outside of stress generating patterns is higher than a bottom surface of the stress generating patterns.

4. The semiconductor device of claim 1, wherein a size of the stress generating patterns is maintained constant, independent of a distance between a device isolation layer surrounding the first semiconductor pattern and the gate electrode.

5. The semiconductor device of claim 1, wherein the stress generating patterns apply a compression stress to the first semiconductor pattern therebetween.

6. The semiconductor device of claim 2, wherein the stress generating patterns are defined between the first semiconductor pattern and the second semiconductor patterns.

7. The semiconductor device of claim 1, wherein the first semiconductor pattern is silicon, and the stress generating patterns are epitaxial silicon-germanium.

8. The semiconductor device of claim 2, wherein the first semiconductor pattern is silicon, the second semiconductor patterns are epitaxial silicon, and the stress generating patterns are epitaxial silicon-germanium.

9. The semiconductor device of claim 1, wherein the stress generating patterns comprise a silicon nitride layer.

10. The semiconductor device of claim 1, wherein the gate electrode is formed on a top surface and at both sides of the first semiconductor pattern, and
wherein the stress generating patterns are formed on a top surface and at both sides of the first semiconductor pattern under the gate spacer.

11. The semiconductor device of claim 10, wherein a channel is formed on the top surface and at both sides of the first semiconductor pattern under the gate electrode.

12. The semiconductor device of claim 1, further including a buried oxide layer and a supporting semiconductor substrate under the first semiconductor pattern.

13. A semiconductor device comprising:
a semiconductor pattern including source/drain regions, a channel region, and source/drain extension regions, the source/drain extension regions being located between the source/drain regions and the channel region, and being lower in level than the source/drain regions and the channel regions;
a gate electrode formed on the channel region with a gate insulating layer interposed between the gate electrode and the channel region; and
stress generating patterns formed on the source/drain extension regions.

14. The semiconductor device of claim 13, further comprising epitaxial semiconductor patterns formed on the source/drain regions.

15. The semiconductor device of claim 13, wherein the semiconductor pattern is single crystalline silicon, and the stress generating patterns are epitaxial silicon-germanium.

16. The semiconductor device of claim 13, wherein the semiconductor pattern is single crystalline silicon, and the stress generating patterns comprise a silicon nitride layer.

17. The semiconductor device of claim 16, further comprising a buffer layer placed on both sidewalls of the gate electrode,
wherein the stress generating patterns extend on the buffer layer and toward a part of surfaces of the source/drain regions;
wherein an insulating spacer covers the stress generating patterns on the sidewalls of the gate electrode.

18. The semiconductor device of claim 14, wherein the semiconductor pattern is single crystalline silicon, the epitaxial semiconductor pattern is epitaxial silicon, and the stress generating patterns are epitaxial silicon-germanium.

19. The semiconductor device of claim 13, further comprising a silicide layer placed on the source/drain regions.

20. The semiconductor device of claim 13, wherein a size of the stress generating patterns is maintained constant, independent of a distance between a device isolation layer surrounding the first semiconductor pattern and the gate electrode.

21. A method of forming a semiconductor device, comprising:
forming a first semiconductor pattern defining an active region;
forming an insulated gate electrode on the first semiconductor pattern;
forming second semiconductor patterns having intervals on the first semiconductor pattern at both sides of the insulated gate electrode; and
forming stress generating patterns filling the intervals.

22. The method of claim 21, wherein forming the intervals on the first semiconductor pattern at both sides of the insulated gate electrode includes:
forming a sacrificial spacer on both sidewalls of the insulated gate electrode;
forming second semiconductor patterns on the first semiconductor pattern outside the sacrificial spacers; and
removing the sacrificial spacers.

23. The method of claim 22, further comprising etching a part of the first semiconductor pattern exposed by the intervals so as to lower a top surface thereof.

24. The method of claim 23, wherein the second semiconductor patterns are partially and wholly etched when a part of the first semiconductor pattern exposed by the intervals is etched.

25. The method of claim 22, wherein the second semiconductor patterns are formed on the first semiconductor pattern outside the sacrificial spacers by selectively forming an epitaxial layer on the first semiconductor pattern exposed outside of the sacrificial spacers applying an epitaxial growth method.

26. The method of claim 22, wherein the stress generating patterns are formed by forming a hetero-epitaxial layer having a larger lattice constant than the first and second semiconductor patterns applying an epitaxial growth method.

27. The method of claim 26, wherein the first semiconductor pattern is formed of silicon, the second semiconductor patterns are formed of a silicon epitaxial layer, and the stress generating patterns are formed of a silicon-germanium epitaxial layer.

28. The method of claim 22, wherein
forming the stress generating patterns comprises forming a spacer insulating layer,
wherein further comprising:
forming a spacer insulating layer; and
forming insulating spacers by etching-back the spacer insulating layer until the second semiconductor patterns are exposed.

29. The method of claim 22, further comprising forming source/drain regions by implanting impurity ions after forming the sacrificial spacers.

30. The method of claim 29, further comprising forming source/drain extension regions by implanting impurity ions after removing the sacrificial spacers.

31. The method of claim 22, wherein forming the first semiconductor pattern includes:
preparing an SOI substrate in which a supporting semiconductor substrate, a buried oxide layer, and a first semiconductor substrate are sequentially stacked; and
patterning the first semiconductor substrate using an etch mask defining an active region until the buried oxide layer is exposed.

32. The method of claim 22, wherein forming the first semiconductor pattern includes:
preparing a first semiconductor substrate;
etching the first semiconductor substrate to a predetermined depth using an etch mask defining an active region; and
filling insulating materials with the etched portion to form a device isolation layer.

33. A method of a semiconductor device comprising:
forming a first semiconductor pattern defining an active region;
interposing a gate insulating layer on the first semiconductor pattern to form a gate electrode;
interposing a buffer layer on both sidewalls of the gate electrode to form a sacrificial spacer;
forming an epitaxial second semiconductor pattern on the first semiconductor pattern outside the sacrificial spacer;
removing the sacrificial spacer; and
forming stress generating patterns on the first semiconductor pattern exposed by removing the spacer.

34. The method of claim 33, further comprising etching a part of the first semiconductor pattern exposed by removing the sacrificial spacer.

35. The method of claim 34, wherein the epitaxial second semiconductor pattern is partially or wholly removed when a part of the first semiconductor pattern is etched.

36. The method of claim 33, wherein forming stress generating patterns filling intervals between the epitaxial second semiconductor patterns and the gate electrode includes forming a hetero epitaxial third semiconductor pattern having a larger lattice constant than the first semiconductor pattern and the epitaxial second semiconductor pattern.

37. The method of claim 33, wherein forming stress generating patterns filling the intervals between the epitaxial second semiconductor patterns and the gate electrode includes forming a silicon nitride layer.

38. The method of claim 33, wherein the first semiconductor pattern includes an upper surface and two sides, and
wherein the gate electrode is formed on the upper surface and both sides of the first semiconductor pattern so that a channel region is formed on the upper surface and both sides of the first semiconductor pattern.
